(19) United States
(12) Patent Application Publication
(10) Pub. No.: US 2017/0346495 A1
(43) Pub. Date: Nov. 30, 2017

(54) FREQUENCY DIVIDER

(71) Applicant: Nordic Semiconductor ASA, Trondheim (NO)

(72) Inventors: Stein Erik Weberg, Trondheim (NO); Johnny Pihl, Trondheim (NO)

(73) Assignee: Nordic Semiconductor ASA, Trondheim (NO)

(21) Appl. No.: 15/537,197

(22) PCT Filed: Dec. 11, 2015
(86) PCT No.: PCT/GB2015/053864

§ 371 Date: Jun. 16, 2017

(30) Foreign Application Priority Data
Dec. 16, 2014 (GB) 1422352.3

(51) Int. Cl. H03L 7/193

(52) U.S. Cl. CPC H03L 7/193

(57) ABSTRACT

A variable frequency divider arrangement is arranged to divide a frequency of an incoming signal by a variable number D to provide a resultant signal. The arrangement comprises:
a first counter having a first clock input and a first output undergoing a single cycle for P cycles of said first clock if a first control input is in a first state or undergoing a single cycle for P+1 cycles of said first clock if said first control input is in a second state;
a second counter in series with said first counter 108 and having a second clock input and a second output undergoing a single cycle for every N cycles of said second clock, wherein N is an integer predetermined by a second control input; and
a controller arranged to determine said first and second control inputs.

This invention relates to frequency dividers, particularly although not exclusively those used in frequency synthesizers for phase-locked loops for tuning applications in digital radio transmitters and receivers.

In radio communications it is necessary to be able to synthesize periodic signals of varying frequency to tune transmitters and receivers employing different pre-defined channels. Typically a phase locked loop (PLL) is employed for this purpose. Frequency variation is achieved by a variable count frequency divider in the feedback loop of the PLL.

Programmable frequency dividers with a variable-modulus pre-scaler (VMP) are known for use in the feedback loop of a PLL. However the Applicant has appreciated that the known arrangements suffer from a drawback in some circumstances since they will typically give a very uneven duty cycle. Whereas this is not necessarily a problem in a typical PLL itself where an edge-triggered phase detector is used, the Applicant has appreciated that by addressing it, the resultant clock signal can be used for other purposes without having to provide a further dedicated clock.

When viewed from a first aspect the invention provides a variable frequency divider arrangement arranged to divide a frequency of an incoming signal by a variable number D to provide a resultant signal, the arrangement comprising:
a first counter having a first clock input and a first output undergoing a single cycle for P cycles of said first clock if a first control input is in a first state or undergoing a single cycle for P+1 cycles of said first clock if said first control input is in a second state;
a second counter in series with said first counter and having a second clock input and a second output undergoing a single cycle for every N cycles of said second clock, wherein N is an integer predetermined by a second control input; and
a controller arranged to determine said first and second control inputs such that said first control input is in said second state for a number A of first clock cycles such that D=N*P+A and wherein said controller is arranged to select N and A such that the resultant signal has cumulative high and low times which are the same to within half a cycle of said second clock input.

Thus it will be seen by those skilled in the art that in accordance with the invention, the frequency divider is implemented in two stages, which is efficient in terms of clock speed and power, and that for given values of D and P the values of N and A may be selected from a range of odd and even integers to provide a more even duty cycle. This is advantageous as it allows the resulting clock to be used for other parts of a circuit which require a stable frequency clock that implies the duty cycle must be close to 50%. A straight-forward implementation of a variable frequency divider does not achieve this.

In a set of embodiments the divider further comprises an arrangement which translates said resultant signal into a clock signal having double the frequency. The frequency doubling is advantageous as it provides a higher frequency clock synchronous to the second counter output and this has proven useful for other parts of a circuit into which the frequency divider arrangement is incorporated.

In a set of embodiments said controller is arranged to determine a value for N and

A based on a value for D using a lookup table. This allows the values to be optimised for any given situation and thus a duty cycle close to 50% to be achieved. In some embodiments a duty cycle deviation of less than 0.5% from 50% may be achieved. This contrast with prior art implementations where a duty cycle variation of 5% is typical.

The Applicant has further appreciated that the placement of extended-length pulses can be significant and thus in a set of embodiments the lookup table also specifies at which part of the cycle to place one or more extended-length pulses. In a set of embodiments for example the extended length pulse is placed on the shortest half-cycle of the output clock for at least some division values. This may be done when N is odd and A is high enough to balance the duty cycle error arising from this. If A is not high enough to balance the duty cycle error, N can be decreased by 1 (thereby making it even) and A increased by P. Where N is even the extended length pulse may be placed equally in the first and second half cycles of the output clock.

The Applicant has appreciated that such an approach is novel and inventive in its own right and this when viewed from a second aspect the invention provides a variable frequency divider arrangement arranged to divide a frequency of an incoming signal by a variable number D to provide a resultant signal, the arrangement comprising:
a first counter having a first clock input and a first output undergoing a single cycle for P cycles of said first clock if a first control input is in a first state or undergoing a single cycle for P+1 cycles of said first clock if said first control input is in a second state;
a second counter in series with said first counter and having a second clock input and a second output undergoing a single cycle for every N cycles of said second clock, wherein N is an integer predetermined by a second control input; and a controller arranged to determine said first and second control inputs such that said first control input is in said second state for a number A of first clock cycles such that D=N*P+A and wherein said controller is arranged to determine where in the cycle of the second counter the first control input is in said second state such that the resultant signal has cumulative high and low times which are the same to within half a cycle of said second clock input.

The invention extends to a phase-locked loop comprising the frequency divider in accordance with either aspect of the invention. In a set of embodiments the phase locked loop is used in a digital radio transmitter or receiver.

An embodiment of the invention will now be described, by way of example only, with reference to the accompanying drawings in which:

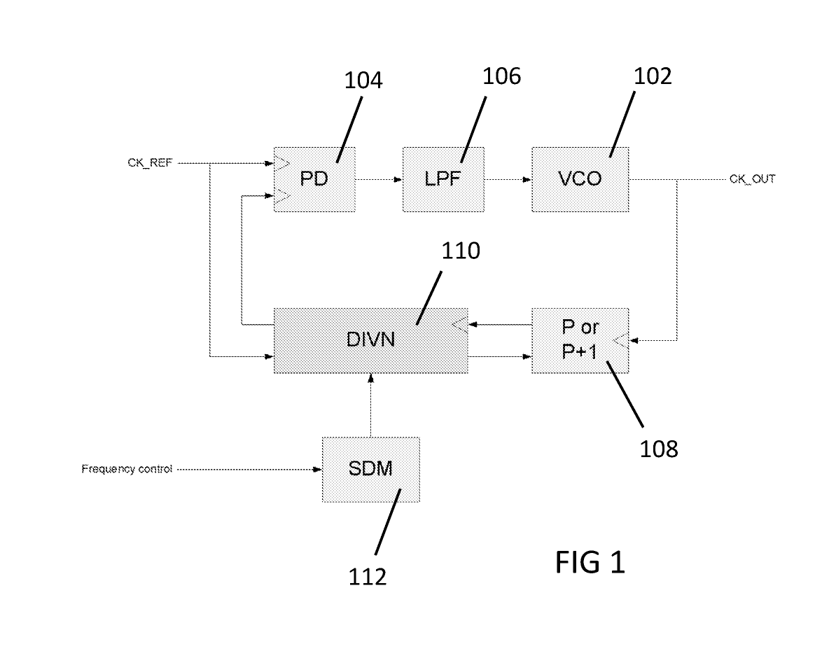

FIG. 1 is a schematic diagram of a phase locked loop to which the invention may be applied;

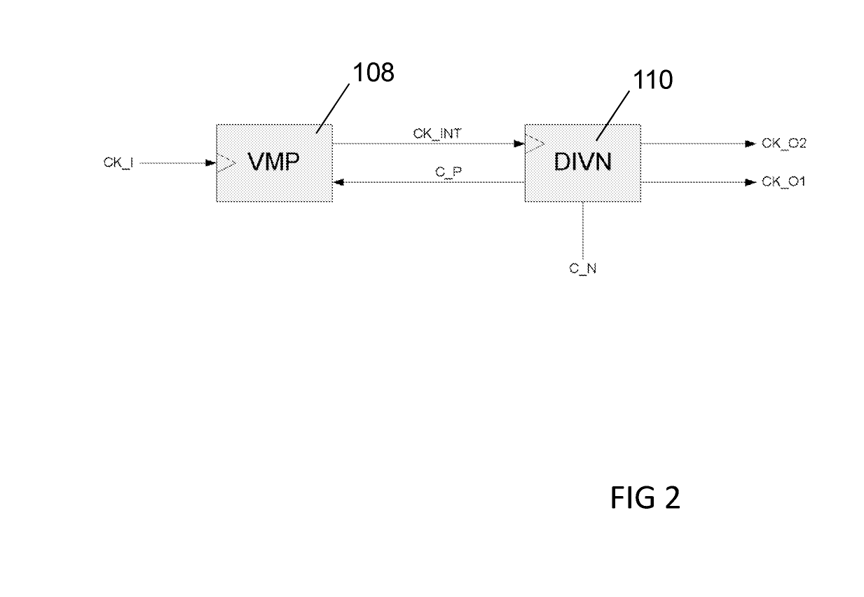

FIG. 2 is a more detailed representation of a frequency divider in accordance with an embodiment of the invention;

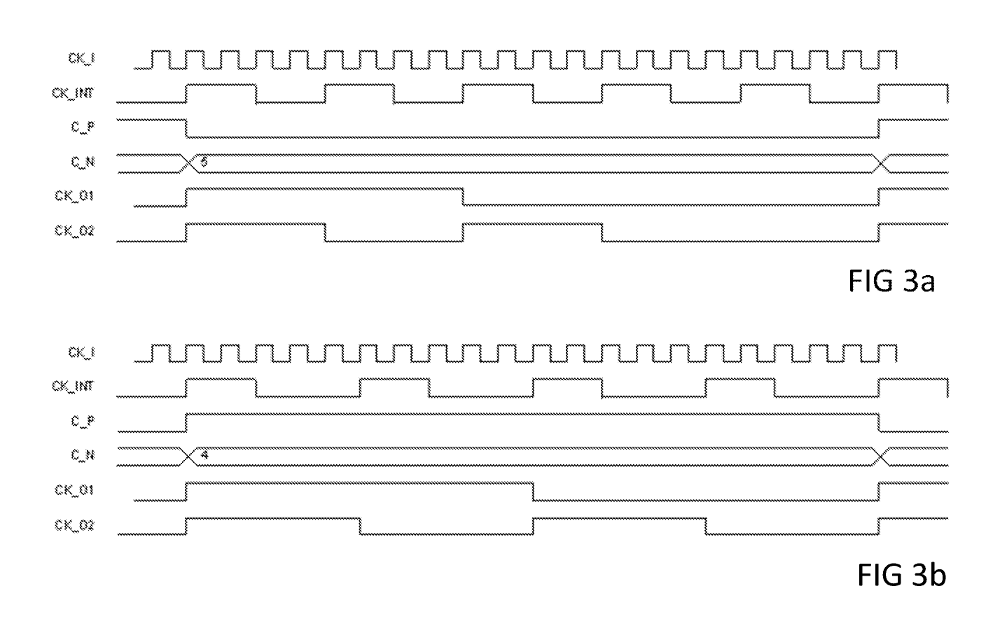

FIG. 3a is a timing diagram showing possible operation of the frequency divider in a conventional configuration;

FIG. 3b is a timing diagram showing possible operation of the frequency divider in accordance with an embodiment of the invention;

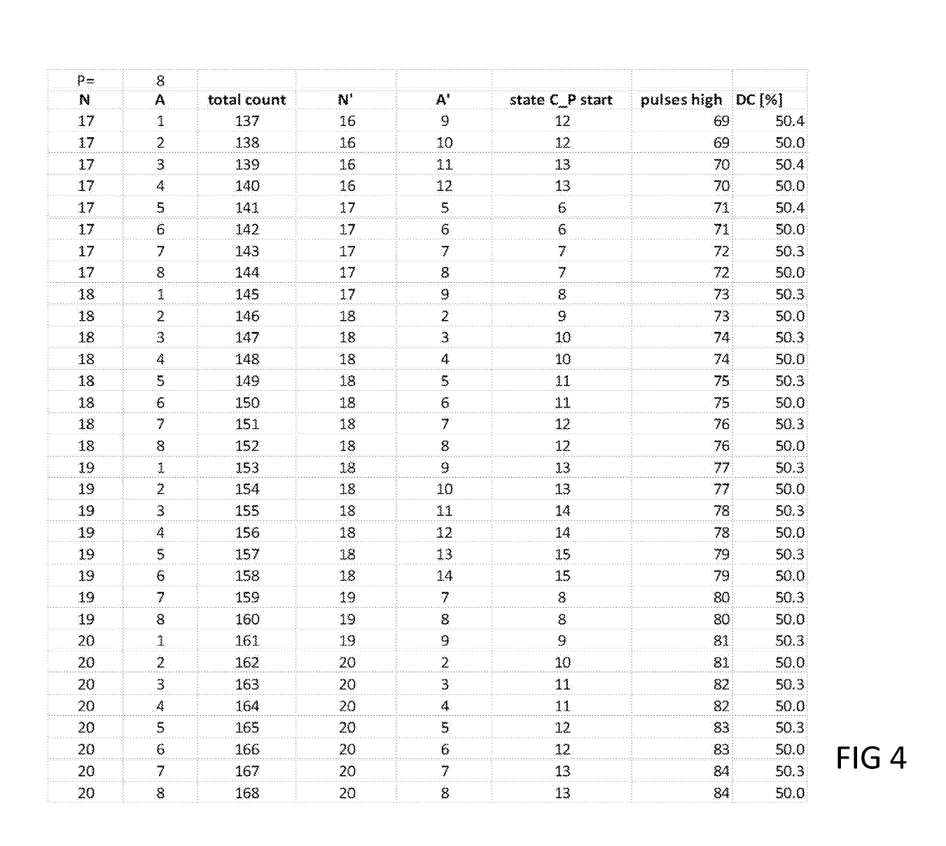

FIG. 4 is a look-up table which illustrates a mapping in accordance with an embodiment of the invention from simplistic parameters and modified parameters;

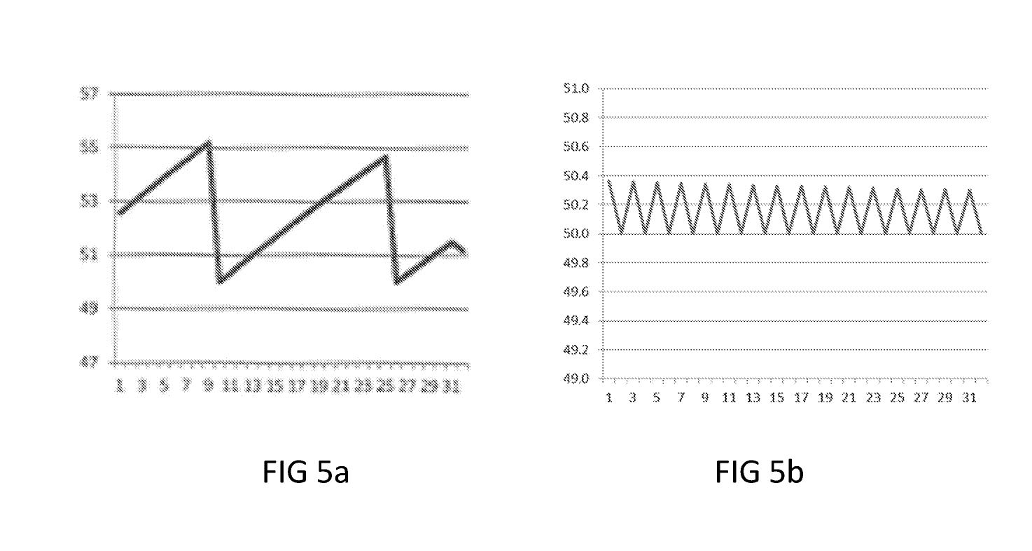

FIG. 5a is a plot of duty cycle against channel number (related to total count) for the simplistic parameters of FIG. 4;

FIG. 5b is a plot of duty cycle against channel number (related to total count) for the modified parameters of FIG. 4; and

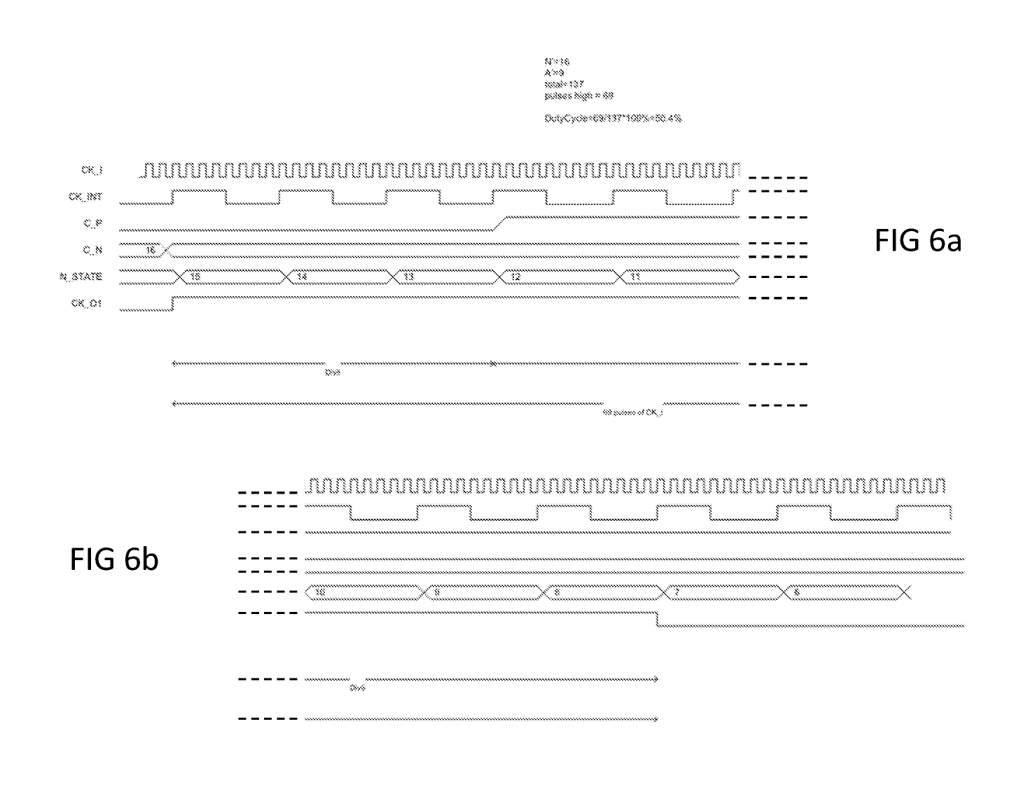

FIGS. 6a and 6b are two respective halves of a timing diagram corresponding to the first row in the table of FIG. 4.

A conventional fractional N phase locked-loop (PLL) to which the invention can be applied is shown in FIG. 1. As with any PLL this is based on a voltage controlled oscillator (VCO) 102 which is controlled by a phase detector 104 via a low-pass filter 106. The phase detector 104 causes small adjustments to the frequency of the VCO 102 in order to bring the phase (and therefore frequency) of the fed-back signal into alignment with the reference clock CK_REF. It will be noted that the VCO 102 is running at the output frequency CK_OUT.

A variable modulus pre-scaler (VMP) circuit 108 is used to divide the frequency by P or P+1 depending upon the control signal it receives from a further divider module 110, which divides the frequency by a further integer N before feeding the phase detector 104. The frequency of the VCO 102 is therefore controlled to be F_{ref}*N*(nP+m(P+1)) where F_{ref} is the reference crystal frequency and n and m are the relative proportions of the occurrences of the respective counts P and P+1 over a given time period.

The divider module 110 is controlled by a sigma-delta modulator (SDM) 112 to determine the above-mentioned relative proportions of P and P+1 counts, so determining the precise frequency. In this circuit there is inevitably quantisation noise coming from the SDM 112 corresponding to steps of 32 MHz (the reference frequency, F_{ref}).

The precisely divided average frequency signal is fed to the phase detector 104 which generates an output signal to control the VCO 102 in accordance with any mismatch between the signal from the divider 110 and the reference clock input signal CK_REF. Since the divided clock is used as an input to an edge-triggered phase detector, its duty cycle is not critical. However it will generally be significantly different from 50%.

FIG. 2 shows in more detail a frequency divider arrangement used in accordance with the invention. The overall frequency division is split between two modules. The first is a pre-scaler 108 which has a variable modulus so that it can divide by P or P+1 depending on a control signal C_P. The pre-scaler 108 could be an asynchronous or ripple counter but this is not essential. The second module is a counter 110, which may be a synchronous counter that operates on the divided clock and divides by an amount N determined by its control input C_N. The resulting frequency division can therefore be expressed as N*P+A where A represents how many times during one output cycle the VMP 108 has divided by P+1. The DIVN module 110 also provides the control input C_P to the VMP 108.

The input clock, CK_I for the VMP 108 is provided by the output of the VCO 102 (see FIG. 1). The VMP 108 produces an intermediate clock C_INT which is passed to the DIVN module 110. The outputs from the DIVN module are a clock signal CK_O1 which is passed to the phase detector 104 (FIG. 1) and a second clock output, CK_O2 at double the frequency of CK_O1 and which is used for another purpose on the integrated circuit. The external output clock CK_O2 is required to have a very stable frequency. This is equivalent to a requirement for CK_O1 to have a duty cycle very close to 50% at all times. A standard implementation of a split frequency divider of the type shown does not achieve this. However by appropriate selections of values for N, P and A, this can be achieved as demonstrated in FIGS. 3a and 3b.

FIG. 3a shows a notional conventional implementation of a split frequency divider of the type shown in FIG. 2 to give a total division count of 20. The top plot CK_I is the initial input frequency as provided by the VCO 102. In this example the value of P is taken to be 4 and thus the pre-scaler 108 is set to divide the CK_I by 4 which yields the second plot, CK_INT at ¼ the frequency of CK_I. To achieve the overall count of 20, the divider 110 is set to divide by 5 (i.e. N=5 to so that N*P=20) To achieve a count of 20 is not necessary to add any additional counts so that A=0. In other words a static count is used in the pre-scaler 108 in this example. This means that the control signal C_P (third plot) is maintained low during the period shown.

The division by 5 of the DIVN module 110 is implemented by setting the counter to C_N−1=4 and then counting down to 0. The resultant clock signal C_O1 is shown in the fifth plot. This shows the clock output signal CK_O1 is high for two cycles of the CK_INT signal by which the DIVN module 110 is clocked, and low for three cycles. Of course the length of each half-cycle is unequal as is inevitable when dividing by an odd number but this does not matter for the purposes of the edge-triggered phase detector 104.

The final plot is the double-frequency output clock CK_O2. This is realised by defining internal states where the output should rise or fall. In this example the CK_O2 output is set to go high whenever the CK_O1 output has a transition (low to high or high to low), then go low again after one cycle of CK_INT. As can be seen from the fifth plot of FIG. 3a, this results in a signal which indeed has an average frequency twice that of CK_O1, although its instantaneous frequency is very different from one cycle to the next: The first cycle at CK_O2 corresponds to eight cycles at CK_I while the second cycle corresponds to 12 cycles of CK_I. This would not make it appropriate for use in another application elsewhere in the device which required a very stable frequency.

FIG. 3b shows how the same division by 20 can be achieved in accordance with the invention by setting the pre-scaler 108 to count to 5 and the DIVN module 110 to count to 4. As before the top plot CK_I is the initial input frequency as provided by the VCO 102. To cause the pre-scaler 108 to divide the CK_I by 5, the control signal C_P (third plot of FIG. 3b) is maintained high during the period shown to cause it to count to P+1=5. This means that there are 4 (=N) extra CK_I cycles and so A=N=4. This yields the second plot of FIG. 3b, CK_INT in which the signal is held low for an extra cycle of CK_I in each CK_INT cycle and so the average frequency is at ⅕ the frequency of CK_I.

To achieve the same overall count of 20, the DIVN divider module 110 is set to divide by 4 this time. The division by 4 by the DIVN module 110 is implemented by switching its control signal C_N (fourth plot) from high to low (or vice versa) for every 4 periods of the pre-scaler count CK_INT. The resultant clock signal C_O1 is shown in the fifth plot. This shows the clock output signal CK_O1 is high for two cycles of the CK_INT signal by which the DIVN module 110 is clocked, and low for two cycles. The length of each half-cycle is now equal.

The double-frequency output clock CK_O2 is derived in the same way: going high whenever the CK_O1 output has a transition, then going low again after one cycle of CK_INT. As can be seen from the fifth plot of FIG. 3b, this also results in a CK_O2 signal which has a an average frequency twice that of CK_O1, but now the clock period is exactly the same from one cycle to the next. This would make it suitable for use in other applications which require a very stable frequency.

While the example given above is a relatively simple one, the principle of adjusting, in accordance with the invention, the relative values of N and A for a given value of P to give a significantly more even duty cycle is clearly illustrated. A more realistic example that also employs count-dependent placement of the C_P pulse can be seen from the table of FIG. 4.

FIG. 4 shows how total counts (and therefore divisions) in the range 137 to 168 can be achieved for a value of P=8. These would allow 32 different counts to be configured. As in previous explanations, N is the count applied by the DIVN module 110. A is the number of extended length (‘P+1’) cycles employed during each cycle of the output clock CK_O1.

The two left hand columns in FIG. 4, headed ‘N’ and ‘A’ respectively show how the required total count in the third column would be made up following a simple ‘conventional’ implementation where total count=N*P+A. This follows the simple cyclical pattern of selecting the highest possible value of N and gradually increasing A until it reaches P (in this case 8) and then incrementing N and restarting. In this exemplary implementation A is selected from the range [1,8]. Equally however an implementation could be employed in which A is set to be in the range [0,7]. It will be noted that if this logical implementation is used the duty cycle of the resulting signal fluctuates significantly as shown in FIG. 5a.

The fourth and fifth columns on the other hand show these values N′ and A′ modified in accordance with the invention. It will be seen that in general N′ is equal to or lower than N and consequently A′ is higher than or equal to A (when N′=N−1; A′=A+P. Although for many of the total count values N′ and A′ are the same as N and A respectively, overall these columns show that by deviating from an ‘automatic’ scheme and providing specific values for each total count, and by specifying the placement of the C_P pulse as will be explained below, the duty cycle can be made very close to 50% as shown in the right hand column and FIG. 5b. In fact in comparison with the original scheme, the duty cycle variation has been reduced from approximately 5% pp to approximately 0.4% pp.

As well as an adjustment to the counts applied by the pre-scaler 108 and DIVN module 110, the Applicant has further appreciated that a more even duty cycle can be achieved by judicious placement of the extended-length pulses—i.e. by appropriate selection of when the C_P signal pulse is applied. This is given in the sixth column of FIG. 4 entitled ‘state C_P start’.

With additional reference to FIGS. 6a and 6b, taking the example of the first row (total count of 137), since the DIVN counter 110 counts down from N−1 to 0, the count starts at 15 at which point the C_P signal is low and so the VMP counts 8 (=P) for one cycle of the DIVN output (CK_INT). This is repeated when the count is at 14 and 13. When the DIVN counter gets to the next value after that, 12 as indicated by the sixth column of FIG. 4, the C_P signal is made to go high for the next 9 cycles of the DIVN output (CK_INT) since A′=9. Thus for these 9 cycles the VMP counts 9 (=P+1). For the remaining 4 cycles of CK_INT the C_P signal is low so that the VMP count is 8 (=P) again. The total count is therefore:

Total count=3*8+9*9+4*8=137

It will be appreciated that in this example the C_P pulse spans the first and second halves of the CK_O1 cycle. Together with the choice of N and A this gives 69 pulses high (penultimate column of FIG. 4) and therefore a duty cycle of 69/137=50.4%.

In another example (not illustrated in a timing diagram) using the total count=141 row, N′=17 and A′=5. The DIVN counter 110 counts down from 16 (=N′−1) at which point the C_P signal is low and so the VMP counts 8 (=P) for each cycle of the DIVN counter. In this case C_P stays low for 10 cycles of the DIVN output (CK_INT). When the DIVN counter gets to 6 as indicated by the sixth column of FIG. 4, the C_P signal is made to go high for the next 5 cycles of the DIVN output (CK_INT) since A=5. Thus for these 5 cycles the VMP counts 9 (=P+1). For the remaining 2 cycles of CK_INT the C_P signal is low so that the VMP count is 8 (=P) again. The total count is therefore:

Total count=10*8+5*9+2*8=141

It will be appreciated that in this example the C_P pulse is skewed slightly towards the second half of the CK_O1 cycle. This gives 71 pulses high and so a duty cycle of 71/141=50.4% is achieved.

Finally using the total count=146 row (also not illustrated), N′=18 and A′=2. The DIVN counter 110 counts down from 17 (=N′−1) at which point the C_P signal is low and so the VMP counts 8 (=P) for each cycle of the DIVN counter. In this case C_P stays low for 8 cycles of the DIVN output (CK_INT). When the DIVN counter gets to 9 as indicated by the sixth column of FIG. 4, the C_P signal is made to go high for the next 2 cycles of the DIVN output (CK_INT) since A=2. Thus for these 2 cycles the VMP counts 9 (=P+1). For the remaining 10 cycles of CK_INT the C_P signal is low so that the VMP count is 8 (=P) again. The total count is therefore:

Total count=8*8+2*9+8*8=146

In this example the C_P pulse exactly spans the first half and second half of the CK_O1 cycle. This gives 73 pulses high and so a duty cycle of 73/146=50.0% is achieved.

The comparison between the original, automatic scheme and the arrangement in accordance with the invention is shown in FIGS. 5a and 5b respectively.

Although a particular modified mapping for N to N′ and A to A′ and a placement in the CK_O1 cycle (as indicated by the state C_P start column) is shown for each value of the total count, this particular mapping and placement is merely an example and different mappings and placements could be applied for different values of P and total count for example. The key is that the provision of a specific mapping and placement for each count value (which may be in the form of a lookup table) allows an advantageous near-50% duty cycle to be achieved.

1. A variable frequency divider arranged to divide a frequency of an incoming signal by a variable number D to provide a resultant signal, the variable frequency divider comprising:
a first counter having a first clock input and a first output undergoing a single cycle for P cycles of said first clock if a first control input is in a first state or undergoing a single cycle for P+1 cycles of said first clock if said first control input is in a second state;
a second counter in series with said first counter and having a second clock input and a second output undergoing a single cycle for every N cycles of said second clock, wherein N is an integer predetermined by a second control input; and
a controller arranged to determine said first and second control inputs such that said first control input is in said second state for a number A of first clock cycles such that D=N*P+A and wherein said controller is arranged to select N and A such that the resultant signal has cumulative high and low times which are the same to within half a cycle of said second clock input.

2. The variable frequency divider of claim 1 further comprising a signal translator which translates said resultant signal into a clock signal having double the frequency of the resultant signal.

3. The variable frequency divider of claim 1 wherein said controller is arranged to determine a value for N and A based on a value for D using a lookup table.

4. The variable frequency divider of claim 3 wherein the lookup table also specifies at which part of the cycle to place one or more extended-length pulses.

5. The variable frequency divider of claim 4 wherein the extended length pulse is placed on the shortest half-cycle of the output clock for at least some division values.

6. The variable frequency divider of claim 4 wherein the extended length pulse is placed equally in the first and second half cycles of the output clock when N is even.

7. A variable frequency divider arranged to divide a frequency of an incoming signal by a variable number D to provide a resultant signal, the variable divider comprising:
a first counter having a first clock input and a first output undergoing a single cycle for P cycles of said first clock if a first control input is in a first state or undergoing a single cycle for P+1 cycles of said first clock if said first control input is in a second state;
a second counter in series with said first counter and having a second clock input and a second output undergoing a single cycle for every N cycles of said second clock, wherein N is an integer predetermined by a second control input; and
a controller arranged to determine said first and second control inputs such that said first control input is in said second state for a number A of first clock cycles such that D=N*P+A and wherein said controller is arranged to determine where in the cycle of the second counter the first control input is in said second state such that the resultant signal has cumulative high and low times which are the same to within half a cycle of said second clock input.

8. The variable frequency divider of claim 7 comprising a lookup table which specifies at which part of the cycle to place one or more extended-length pulses.

9. The variable frequency divider of claim 8 wherein the extended length pulse is placed on the shortest half-cycle of the output clock for at least some division values.

10. The variable frequency divider of claim 8 wherein the extended length pulse is placed equally in the first and second half cycles of the output clock when N is even.

11. A phase-locked loop comprising the frequency divider of claim 1.

12. A digital radio transmitter or receiver comprising the phase locked loop of claim 11.

13. A phase-locked loop comprising the frequency divider of claim 7.

14. A digital radio transmitter or receiver comprising the phase locked loop of claim 7.
